(19) United States
(12) Patent Application Publication
(10) Pub. No.: US 2026/0094654 A1
(43) Pub. Date: Apr. 2, 2026

(54) FLASH MEMORY APPARATUS AND ERASING METHOD THEREOF

(71) Applicant: Winbond Electronics Corp., Taichung City (TW)

(72) Inventors: Fang Li Li, Taichung (TW); Cheng Han Lee, Taichung (TW)

(73) Assignee: Winbond Electronics Corp., Taichung City (TW)

(21) Appl. No.: 19/019,538

(22) Filed: Jan. 14, 2025

(30) Foreign Application Priority Data
Sep. 27, 2024 (TW) 113136916

(51) Int. Cl. G11C 16/34; G11C 16/16

(52) U.S. Cl. CPC G11C 16/3472; G11C 16/16; G11C 16/3495

(57) ABSTRACT

A flash memory apparatus and an erasing method thereof are provided. The erasing method includes the following steps. Memory blocks are operated according to an operation command. After any one of the memory blocks undergoes a program/erase cycling, whether an accumulated cycle count of the program/erase cycling of the any one of the memory blocks reaches one of multiple interruption points is determined. When the cycle count of the any one of the memory blocks reaches the one of the interruption points, a current pulse count value of a step pulse required for the any one of the memory blocks to pass an erase verification during the program/erase cycling is recorded. An erase verification voltage for the erase verification is adjusted according to the current pulse count value.

### CROSS-REFERENCE TO RELATED APPLICATION

This application claims the priority benefit of Taiwan application serial no. 113136916, filed on Sep. 27, 2024. The entirety of the above-mentioned patent application is hereby incorporated by reference herein and made a part of this specification.

### BACKGROUND

### Technical Field

The disclosure relates to a memory apparatus, and in particular to a flash memory apparatus capable of dynamically adjusting an erase verification voltage, and an erasing method adopted by the apparatus.

### Description of Related Art

NAND-type flash memory apparatuses may adopt an incremental step pulse erase (ISPE) method to perform erase verification by comparing the threshold voltage with the erase verification voltage. When the number of program/erase cycling is low, setting the erase verification voltage too high may lead to severe program interference. When the number of program/erase cycling is high, setting the erase verification voltage too low may cause severe cycling degradation. Therefore, how to achieve a good balance between program interference and cycling degradation is a key issue that needs research efforts in this field.

### SUMMARY

The disclosure provides a flash memory apparatus and an erasing method capable of dynamically adjusting an erase verification voltage to achieve an effective balance between a program interference and a cycling degradation.

An erasing method of a flash memory apparatus of the disclosure is applicable to a flash memory apparatus with multiple memory blocks. The erasing method includes the following steps. The memory blocks are operated according to an operation command. After any one of the memory blocks undergoes a program/erase cycling, whether an accumulated cycle count of the program/erase cycling reaches one of multiple interruption points is determined. When the cycle count for the any memory block reaches one of the interruption points, a current pulse count value of a step pulse required for the block to pass an erase verification during the program/erase cycling is recorded. An erase verification voltage for the erase verification is then adjusted according to the current pulse count value.

A flash memory apparatus of the disclosure includes a memory array, a register, and a memory control circuit. The memory array includes multiple memory blocks, and the memory control circuit is coupled to both the memory array and the register. The memory control circuit is configured to operate the memory blocks according to an operation command, and determine whether an accumulated cycle count reaches one of multiple interruption points after a program/erase cycling, record a current pulse count value of a step pulse required for any one of the memory blocks to pass an erase verification during the program/erase cycling into the register when the cycle count of any one of the memory blocks reaches one of the interruption points, and adjust an erase verification voltage for the erase verification according to the recorded pulse count value.

Based on the above, the flash memory apparatus and the erasing method thereof may be used to dynamically adjust the erase verification voltage according to changes in the pulse count value (an erase-shot-number) required for erase verification. This approach avoids program interference at the early stages of program/erase cycling and reduces cycling degradation at later stages, achieving a good balance between program interference and cycling degradation. This ultimately improves the endurance and cycling performance of the product at each stage.

### BRIEF DESCRIPTION OF THE DRAWINGS

FIG. 1 illustrates a schematic overview in an embodiment of a flash memory apparatus of the disclosure.

FIG. 2 illustrates a flowchart of the steps of an erasing method of the flash memory apparatus in an embodiment of the disclosure.

FIG. 3 illustrates a flowchart of the steps in a recording method of an initial pulse count value in an embodiment of the disclosure.

FIGS. 4A and 4B illustrate diagrams showing a relationship between a cycle count and an erase verification voltage as well as a failure rate increase in an embodiment of the disclosure.

### DESCRIPTION OF THE EMBODIMENTS

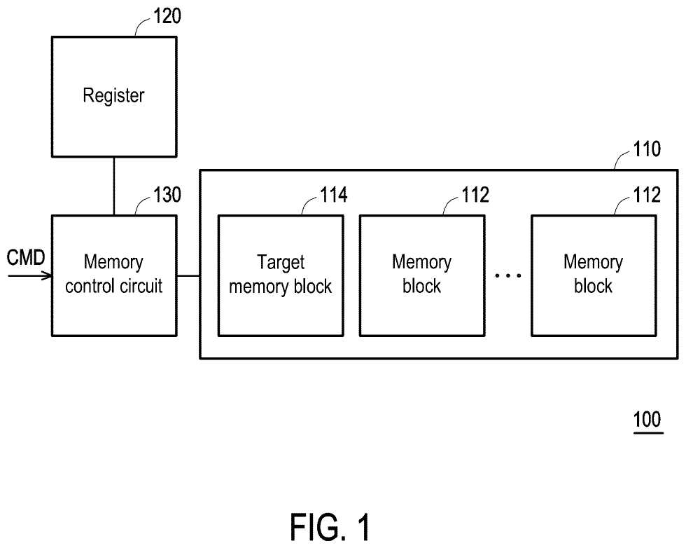

Referring to FIG. 1, a flash memory apparatus 100 in an embodiment of the disclosure, which may be a NAND-type, includes a memory array 110, a register 120, and a memory control circuit 130. The memory array 110 includes multiple memory blocks 112. Each memory block 112 includes multiple memory cells. In this embodiment of the disclosure, there are no restrictions on the number of memory blocks 112 or memory cells.

The memory control circuit 130 is coupled to the memory array 110 and the register 120. The memory control circuit 130 may be configured to select one or more memory blocks from among the multiple memory blocks 112 in the memory array 110 to perform specified operations (such as erasing or programming) according to an operation command CMD it receives. The multiple memory blocks 112 may each correspond to an individual erase verification voltage EV. For illustration purposes, any memory block 112 that has undergone a program/erase cycling and is determined as needing an adjustment to its corresponding erase verification voltage EV may be referred to as a target memory block 114.

The memory control circuit 130 illustrated in FIG. 1 is located within the flash memory apparatus 100; however, the memory control circuit 130 may also be an apparatus separate from the flash memory apparatus 100. The register 120, which may be composed of non-volatile memory, could also be integrated into the memory control circuit 130. The disclosure is not limited by this configuration.

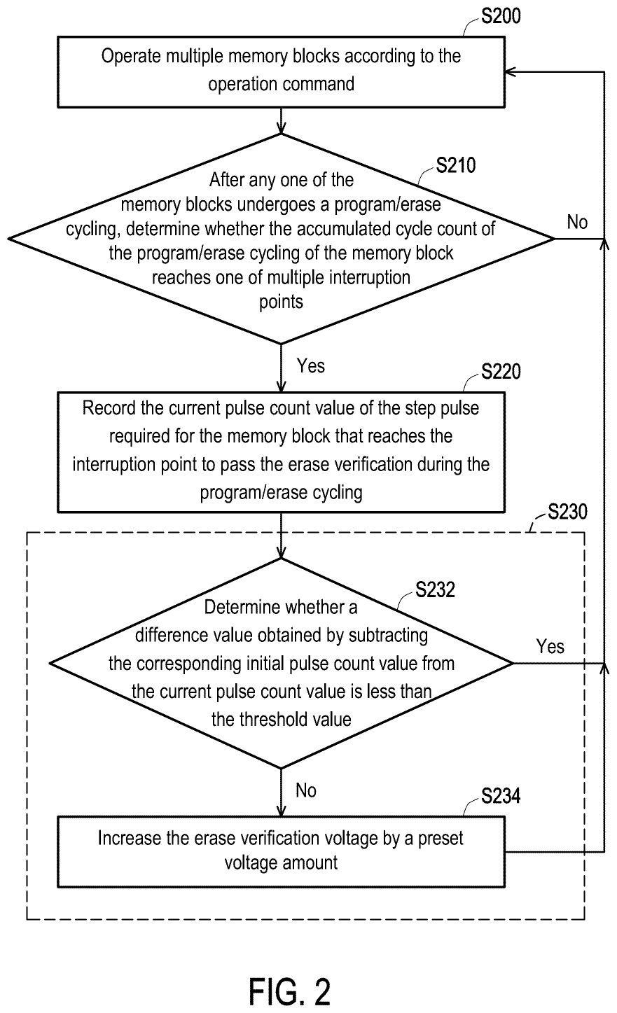

Referring to FIGS. 1 and 2, the erasing method in this embodiment applies to the flash memory apparatus 100 shown in FIG. 1. The steps of the erasing method of the embodiment of the disclosure are described below in conjunction with the components of the flash memory apparatus 100.

In step S200, the memory control circuit 130 operates the multiple memory blocks 112 according to an operation command CMD. Specifically, based on the received operation command CMD, the memory control circuit 130 selects one or more memory blocks from among the multiple memory blocks 112 to perform the specified operation.

In step S210, after any one of the multiple memory blocks 112 undergoes a program/erase cycling, the memory control circuit 130 determines whether an accumulated cycle count CNT of this memory block (referred to as the target memory block 114) in the program/erase cycling has reached one of multiple interruption points. Specifically, the memory control circuit 130 may set multiple interruption points at intervals of a preset count within a count range. For example, the count range may be from 0 cycles to 100k cycles, and the preset count may be 5k or 10k cycles. When the preset count is 5k, the first interruption point is at 5k cycles, the second at 10k cycles, the third at 15k cycles, and so on, until exceeding the count range. In other words, the memory control circuit 130 may determine whether the cycle count CNT of the target memory block 114 after the program/erase cycling reaches any of the preset interruption points.

When the cycle count CNT of the target memory block 114 has not reached any interruption point, it returns to step S200 to continue the operation.

When the cycle count CNT of the target memory block 114 reaches one of the interruption points, in step S220, the memory control circuit 130 records the current pulse count value required for the target memory block 114 to pass the erase verification during the program/erase cycling into the register 120. For example, the memory control circuit 130 may include a counter or any type of component or circuit with counting functionality to count the pulse count value of the step pulses needed to perform erase verification for each memory block 112 using the incremental step pulse erase method. The current pulse count value is then recorded in the register 120.

Finally, in step S230, the memory control circuit 130 adjusts the erase verification voltage EV for the erase verification based on the current pulse count value. Specifically, as shown in FIG. 2, step S230 includes steps S232 and S234. In step S232, the memory control circuit 130 determines whether a difference value obtained by subtracting the corresponding initial pulse count value from the current pulse count value is less than a threshold value. The initial pulse count value is the pulse count value of the step pulses required for each memory block 112 to initially pass the erase verification. Each memory block 112 may correspond to a separate initial pulse count value, and these initial pulse count values have been pre-recorded in the register 120. The threshold value may be, for example, 10 cycles, but this is not limiting. A person having ordinary skill in the art may adjust the threshold value size as needed, based on the teachings of this embodiment.

When the calculated difference value is less than the threshold value, it indicates that the effect of cycling degradation is not significant. At this point, the memory control circuit 130 does not adjust the erase verification voltage EV, and it returns to step S200 to determine, based on the current pulse count value, whether it is necessary to adjust the erase verification voltage EV when the cycle count CNT reaches the next interruption point.

When the calculated difference value is not less than the threshold value, it indicates that the effect of cycling degradation is gradually increasing. At this point, in step S234, the memory control circuit 130 increases the erase verification voltage EV by a preset voltage amount. The preset voltage amount may be less than 1 volt. After the erase verification voltage EV is adjusted, it also returns to step S200 to determine, based on the current pulse count value, whether it is necessary to adjust the erase verification voltage EV when the cycle count CNT reaches the next interruption point. It should be noted that the memory control circuit 130 may set the initial value of the erase verification voltage EV to be relatively low (e.g., −1.2 volts) and increase the erase verification voltage EV each time the difference value is not less than the threshold value. The erase verification voltage EV will not exceed the read voltage used for the memory array 110.

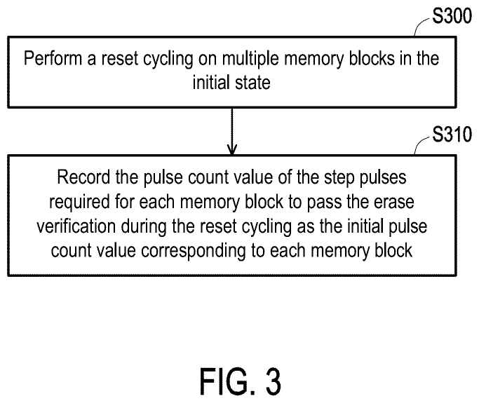

FIG. 3 illustrates an example method for recording the initial pulse count values. Referring to FIG. 3, in step S300, the memory control circuit 130 performs a reset cycling on multiple memory blocks 112 in an initial state. The term “initial state” refers to a condition where the memory has not undergone any erase or program operations (a brand-new, unused memory). The reset cycling sequentially includes a first erase operation, a program operation, and a second erase operation.

Next, in step S310, the memory control circuit 130 records the pulse count value of the step pulses required for each memory block 112 to pass erase verification during the reset cycling (for example, during the second erase operation mentioned above) as the initial pulse count value corresponding to each memory block 112 in the register 120. It should be noted that the steps shown in FIG. 3 occur before the steps shown in FIG. 2.

Through the above method, since the erase verification voltage EV is relatively low when the number of program/erase cycling is low, the effect of program interference may be reduced. Additionally, by tracking changes in the pulse count value of the step pulses required for erase verification after numerous program/erase cycling, it may be determined whether the effect of cycling degradation has become significantly high, and when this effect gradually increases, the erase verification voltage EV is increased to reduce the impact of cycling degradation. In this way, by dynamically adjusting the erase verification voltage EV, both program interference and cycling degradation may be avoided, achieving a good balance between these factors.

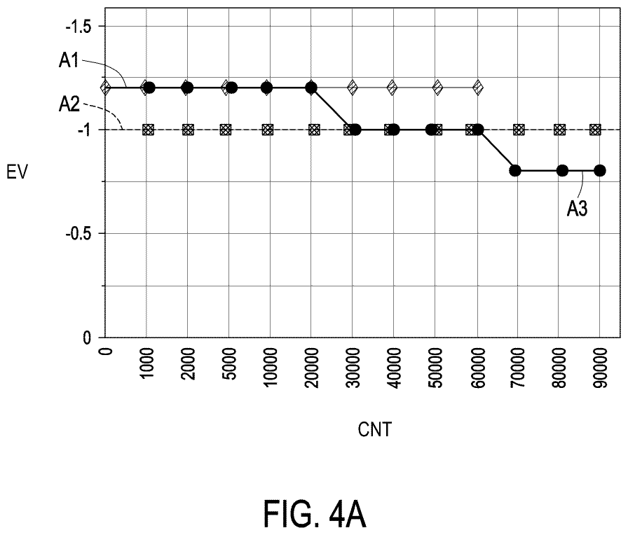

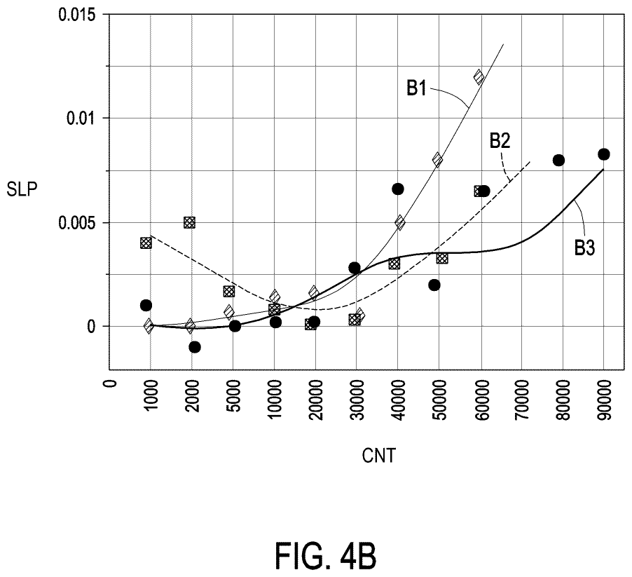

The technical effect of dynamically adjusting the erase verification voltage EV in this case is illustrated below. Referring to FIG. 4A, the horizontal axis represents the accumulated cycle count CNT of program/erase cycling, and the vertical axis represents the set erase verification voltage EV. The erase verification voltage EV represented by curve A1 is fixed at −1.2 volts and does not change as the cycle count CNT increases. The erase verification voltage EV represented by curve A2 is fixed at −1 volt and also does not change as the cycle count CNT increases. The erase verification voltage EV represented by curve A3, however, is dynamically adjusted and changes as the cycle count CNT increases. As shown in FIG. 4A, when the cycle count CNT accumulates to over 20,000 cycles, the erase verification voltage EV represented by curve A3 increases from −1.2 volts to −1 volt. When the cycle count CNT accumulates to over 60,000 cycles, the erase verification voltage EV represented by curve A3 increases from −1 volt to −0.8 volts. To distinguish curves A1 through A3, the connection points of curve A1 are marked with diamonds, curve A2 with squares, and curve A3 with circles in FIG. 4A.

Next, referring to FIG. 4B, the horizontal axis represents the accumulated cycle count CNT of program/erase cycles, and the vertical axis represents a failure rate increase SLP. In this embodiment, the failure rate increase SLP equals the increase in read failures of memory cells within a memory block 112 after program/erase cycles, divided by the increase in cycle count CNT. In FIG. 4B, diamond points correspond to curve A1 in FIG. 4A, representing the failure rate increase SLP when the erase verification voltage EV is fixed at −1.2 volts. Square points correspond to curve A2 in FIG. 4A, representing the failure rate increase SLP when the erase verification voltage EV is fixed at −1 volt. Circular points correspond to curve A3 in FIG. 4A, representing the failure rate increase SLP when the erase verification voltage EV is dynamically adjusted. Curves B1, B2, and B3, represented by a fine solid line, a dashed line, and a bold solid line respectively, are generated using the same algorithm, reflecting the trend of the diamond, square, and circular points in FIG. 4B.

As seen in FIG. 4B, when the erase verification voltage EV is fixed at a specific value, the failure rate increase SLP of curve B2 is higher than that of curve B1 in the early stage of program/erase cycling (e.g., when the cycle count CNT is less than 20,000). In the later stage of program/erase cycling (e.g., when the cycle count CNT exceeds 60,000), the failure rate increase SLP of curve B1 is higher than that of curve B2. In contrast, when comparing with the dynamic adjustment of the erase verification voltage EV, the failure rate increase SLP of curve B3 is not significantly different from that of curve B1 in the early stage of program/erase cycling, while in the later stage, the failure rate increase SLP of curve B3 is lower than that of both curves B1 and B2. This demonstrates that dynamically adjusting the erase verification voltage EV helps achieve a good balance between program interference and cycling degradation, thereby improving cycling performance at each stage.

In summary, the flash memory apparatus and erasing method of the disclosure dynamically adjust the erase verification voltage according to changes in the pulse count value of the step pulses required for erase verification. This approach enables a good balance between program interference and cycling degradation, reduces the deterioration rate of memory cells, and thus improves product endurance and cycling performance at each stage.

What is claimed is:

1. An erasing method of a flash memory apparatus, wherein the flash memory apparatus comprises a plurality of memory blocks, and the erasing method comprises:
operating the plurality of memory blocks according to an operation command;
after any one of the plurality of memory blocks undergoes a program/erase cycling, determining whether an accumulated cycle count of the program/erase cycling of the any one of the plurality of memory blocks reaches one of a plurality of interruption points;
when the cycle count of the any one of the plurality of memory blocks reaches the one of the plurality of interruption points, recording a current pulse count value of a step pulse required for the any one of the plurality of memory blocks to pass an erase verification during the program/erase cycling; and
adjusting an erase verification voltage for the erase verification according to the current pulse count value.

2. The erasing method according to claim 1, wherein adjusting the erase verification voltage for the erase verification according to the current pulse count value comprises:
determining whether a difference value obtained by subtracting a corresponding initial pulse count value from the current pulse count value is less than a threshold value; and
when the difference value is less than the threshold value, increasing the erase verification voltage by a preset voltage amount.

3. The erasing method according to claim 2, further comprising:
performing a reset cycling on the plurality of memory blocks in an initial state; and
recording a pulse count value of the step pulse required for each of the plurality of memory blocks to pass the erase verification during the reset cycling as the corresponding initial pulse count value for the each of the plurality of memory blocks.

4. The erasing method according to claim 3, wherein the reset cycling sequentially comprises a first erase operation, a program operation, and a second erase operation.

5. The erasing method according to claim 1, further comprising:
setting the plurality of interruption points at an interval of a preset count within a count range.

6. The erasing method according to claim 2, wherein the preset voltage amount is less than 1 volt.

7. The erasing method according to claim 5, wherein the count range is from 0 cycles to 100k cycles.

8. The erasing method according to claim 2, wherein the threshold value is 10 cycles.

9. The erasing method according to claim 1, wherein the erase verification voltage does not exceed a read voltage used for a memory array.

10. A flash memory apparatus, comprising:
a memory array, comprising a plurality of memory blocks;
a register; and
a memory control circuit, coupled to the memory array and the register, and configured to:
operate the plurality of memory blocks according to an operation command;
after any one of the plurality of memory blocks undergoes a program/erase cycling, determining whether an accumulated cycle count of the program/erase cycling of the any one of the plurality of memory blocks reaches one of a plurality of interruption points;
when the cycle count of the any one of the plurality of memory blocks reaches the one of the plurality of interruption points, recording a current pulse count value of a step pulse required for the any one of the plurality of memory blocks to pass an erase verification during the program/erase cycling into the register; and
adjust an erase verification voltage for the erase verification according to the current pulse count value.

11. The flash memory apparatus according to claim 10, wherein the memory control circuit determines whether a difference value obtained by subtracting a corresponding initial pulse count value from the current pulse count value is less than a threshold value, and when the difference value is less than the threshold value, the memory control circuit increases the erase verification voltage by a preset voltage amount.

12. The flash memory apparatus according to claim 11, wherein the memory control circuit performs a reset cycling on the plurality of memory blocks in an initial state, and record a pulse count value of the step pulse required for each of the plurality of memory blocks to pass the erase verification during the reset cycling into the register as the corresponding initial pulse count value for the each of the plurality of memory blocks.

13. The flash memory apparatus according to claim 12, wherein the reset cycling sequentially comprises a first erase operation, a program operation, and a second erase operation.

14. The flash memory apparatus according to claim 10, wherein the memory control circuit sets the plurality of interruption points at an interval of a preset count within a count range.

15. The flash memory apparatus according to claim 11, wherein the preset voltage amount is less than 1 volt.

16. The flash memory apparatus according to claim 14, wherein the count range is from 0 cycles to 100k cycles.

17. The flash memory apparatus according to claim 11, wherein the threshold value is 10 cycles.

18. The flash memory apparatus according to claim 10, wherein the erase verification voltage does not exceed a read voltage used for the memory array.
